(19) United States
(12) Patent Application Publication
(10) Pub. No.: US 2003/0076729 A1
(43) Pub. Date: Apr. 24, 2003

(54) Method and apparatus for reducing average power and increasing cache performance by modulating power supplies

(76) Inventors: Eric S. Fetzer, Longmont, CO (US); Wayne Dervon Kever, Ft Collins, CO (US)

Correspondence Address: HEWLETT-PACKARD COMPANY, Intellectual Property Administration, P.O. Box 272400, Fort Collins, CO, 80527-2400, US

(21) Appl. No.: 10/045,310

(22) Filed: Oct. 24, 2001

(51) Int. Cl. G11C 5/00

(52) U.S. Cl. 365/227

(57) ABSTRACT

A circuit for reducing power in SRAMS and DRAMS is implemented by dynamically controlling a voltage applied to individual memory sections of a semiconductor memory array. Individual sections of memory are isolated from a fixed power supply by inserting one or more PFETs between a fixed power supply and a positive connection, VDD, of an individual memory section. The voltage applied to each memory section is controlled by applying a separate variable voltage to each gate of all PFETs connected to a particular memory section. If a memory section is not accessed, the voltage to that section can be lowered, saving power. If a memory section is accessed, the voltage to that section may be raised, providing more power and shortening read and write times.

### FIELD OF THE INVENTION

This invention relates generally to electronic circuits. More particularly, this invention relates to reducing average power in RAM arrays.

### BACKGROUND OF THE INVENTION

As more electronic circuits are included on a single die, the power dissipated by a single die continues to increase. In order to keep the temperature of a single IC (integrated circuit) at a reasonable temperature, many techniques have been used to cool the IC. For example, elaborate cooling fins have been attached to the substrate of ICs. Also, fans have been positioned near a group of IC's to cool them. In some cases, liquids have been used to reduce the heat produced by ICs. These solutions can be costly and may require a great deal of space, where space is at a premium. If the power on ICs can be reduced while still achieving higher levels of integration, the cost and area of devices that use ICs may be reduced.

The number of bits contained on a semiconductor memory chip, has, on average, quadrupled every three years. As a result, the power that semiconductor memories consume has increased. Computer systems can use large numbers of standalone semiconductor memories. Part of the semiconductor memory used by these computer systems, may be held in standby mode for a certain amount of time. The portion of memory that is held in standby is not accessed for data and as result, has lower power requirements than those parts of semiconductor memory that are accessed. The sections of memory that are not being accessed can be monitored. After identifying memory sections that are not being accessed, the power in these sections may be lowered by reducing the voltage applied to them. When sections of memory are being accessed, the voltage may be increased resulting in shorter read and write times. In this manner, power may be directed to sections of memory that may benefit from a higher voltage and power may be directed away from sections that may not need as much power. The following description of an apparatus and method for controlling the voltage applied to individual memory sections addresses a need in the art to reduce power in ICs and computer systems while maintaining performance requirements.

### SUMMARY OF THE INVENTION

An embodiment of the invention provides a circuit for controlling power in individual memory sections of a semiconductor memory. Individual sections of memory of a semiconductor memory are isolated from a fixed power supply by inserting one or more PFETs between the fixed power supply and the positive connection, VDD, of an individual memory section. The voltage applied to each memory section is controlled by applying a separate variable voltage to each gate of all PFETs connected to a particular memory section. If a memory section is not accessed, the voltage to that section can be lowered, saving power. If a memory section is accessed, the voltage to that section may be raised, providing more power and shortening read and write times. This invention fills a need to reduce overall power on a semiconductor chip while at the same time allowing faster access times.

Other aspects and advantages of the present invention will become apparent from the following detailed description, taken in conjunction with the accompanying drawing, illustrating by way of example the principles of the invention.

### BRIEF DESCRIPTION OF THE DRAWINGS

FIG. 1 is a schematic drawing of semiconductor memory elements connected to a fixed power supply through controlled PFETs.

### DETAILED DESCRIPTION OF THE PREFERRED EMBODIMENT

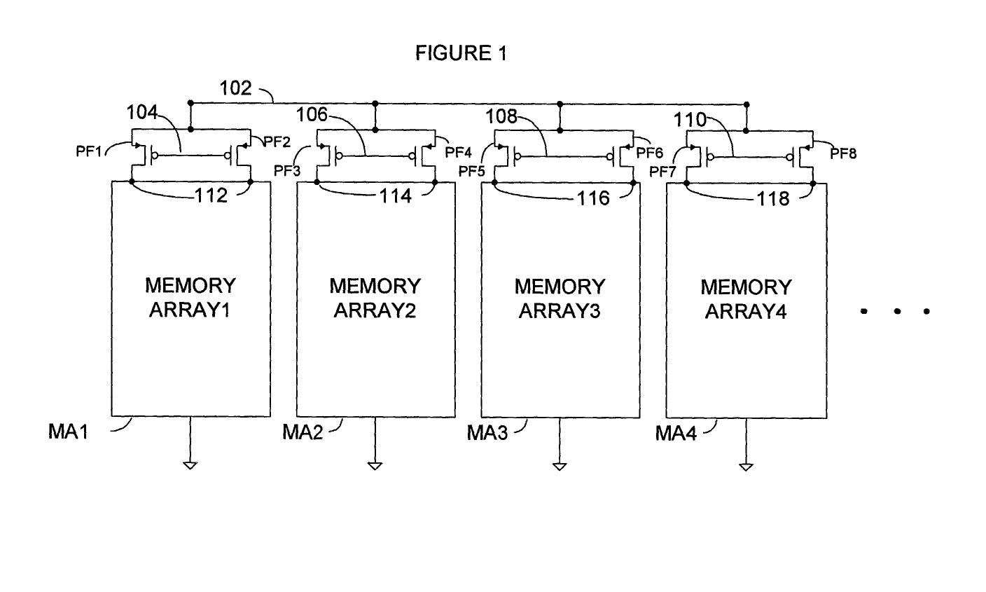

FIG. 1 shows four semiconductor memory arrays, MA1, MA2, MA3, and MA4 connected to a positive power supply, 102 through eight PFETs, PF1 and PF2, PF3 and PF4, PF5 and PF6, and PF7 and PF8 respectively. In this example, the sources of PFETs PF1, PF2, PF3, PF4, PF5, PF6, PF7, and PF8 are electrically connected to positive power supply, 102. The gates of PF1 and PF2 are connected to node 104. Node 104 is driven by a variable voltage source. The gates of PF3 and PF4 are connected to node 106. Node 106 is driven by a variable voltage source. The gates of PF5 and PF6 are connected to node 108. Node 108 is driven by a variable voltage source. The gates of PF7 and PF8 are connected to node 110. Node 110 is driven by a variable voltage source. The drains of PF1 and PF2 are connected to node 112. Node 112 is a positive voltage connection to memory array, MA1. The drains of PF3 and PF4 are connected to node 114. Node 114 is a positive voltage connection to memory array, MA2. The drains of PF5 and PF6 are connected to node 116. Node 116 is a positive voltage connection to memory array, MA3. The drains of PF7 and PF8 are connected to node 118. Node 118 is a positive voltage connection to memory array, MA4.

Power may be better utilized by lowering the voltage on selected memory arrays and raising the voltage on other selected memory arrays. For example, if a “low” voltage is applied at node 104, PFETs, PF1 and PF2 will present a low impedance to current flow and as a result, the voltage on positive voltage connection 112, of memory array, MA1 will be higher than it would have been if a “high” voltage was applied at node 104. A higher voltage on positive voltage connection 112 may allow memory array, MA1 to read and write data in a shorter time however the power dissipated by memory array, MA1 will be higher. By monitoring which memory arrays are active and which are not active, the power can be adjusted by raising the voltage on the active arrays and lowering the voltage on the inactive arrays. For example, if memory arrays MA1 and MA2 are active and MA3 and MA4 are inactive, a “low” voltage would be applied to the gates, 104 and 106, of PFETs PF1, PF2, PF3 and PF4 and a “high” voltage would be applied to the gates, 108 and 110, of PFETs PF5, PF6, PF7, and PF8. This condition would raise the voltage on memory arrays MA1 and MA2 and lower the voltage on memory arrays MA3 and MA4. Memory arrays MA1 and MA2 may have shorter read and write times and memory arrays, MA3 and MA4 would have lower power. As result, more power is directed to the arrays that may benefit from more power.

FIG. 1 shows the use of two PFETs per memory array. This is only an example. One or more PFETs may be used in each section depending on the power needed and how the memory arrays are physically designed.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) A circuit for reducing power in a memory array comprising:
a PFET, said PFET having a drain, source, and a gate;
a variable voltage source;
wherein said drain is electrically connected to a positive terminal of said memory array;
wherein said source is electrically connected to a positive power supply;
wherein said gate is electrically connected to said variable voltage source.

2) A circuit for decreasing read and write times in a memory array comprising
a PFET, said PFET having a drain, source, and a gate;
a variable voltage source;
wherein said drain is electrically connected to a positive terminal of said memory array;
wherein said source is electrically connected to a positive power supply;
wherein said gate is electrically connected to said variable voltage source.

3) A circuit for reducing power in a plurality of memory arrays comprising:
a set of variable voltage sources;
a set of PFETs;
wherein all sources of said set of PFETs are electrically connected to a positive power supply;
wherein a least one drain of a PFET from said set of PFETs is electrically connected to a positive electrical connection of a member of said plurality of memory arrays;
wherein all said memory arrays are connected to a least one drain of said set of PFETs;
wherein at least one gate of a PFET from said set of PFETs is electrically connected to a member of said set of variable voltage sources.

4) The circuit as in claim 3 wherein said pluralities of memory arrays are SRAM arrays.

5) The circuit as in claim 3 wherein said pluralities of memory arrays are register arrays.

6) A method for reducing power in a plurality of memory arrays comprising:
electrically controlling voltage to a gate of each PFET of a set of PFETs;
connecting all sources of said set of PFETs to a positive power supply;
connecting a least one drain of a PFET from said set of PFETS to a positive electrical connection of a member of said plurality of memory arrays;
wherein all said memory arrays are connected to a least one drain of said set of PFETs.

7) The method as in claim 6 wherein said pluralities of memory arrays are SRAM arrays.

8) The method as in claim 6 wherein said pluralities of memory arrays are register arrays.

9) A circuit for decreasing read and write times in a plurality of memory arrays comprising;
a set of variable voltage sources;
a set of PFETs;
wherein all sources of said set of PFETs are electrically connected to a positive power supply;
wherein a least one drain of a PFET from said set of PFETs is electrically connected to a positive electrical connection of a member of said plurality of memory arrays;
wherein all said memory arrays are connected to a least one drain of said set of PFETs;
wherein at least one gate of a PFET from said set of PFETs is electrically connected to a member of said set of variable voltage sources.

10) The circuit as in claim 9 wherein said pluralities of memory arrays are SRAM arrays.

11) The circuit as in claim 9 wherein said pluralities of memory arrays are register arrays.

12) A method for decreasing read and write times in a plurality of memory arrays comprising:
electrically controlling voltage to a gate of each PFET of a set of PFETS;
connecting all sources of said set of PFETs to a positive power supply;
connecting a least one drain of a PFET from said set of PFETS to a positive electrical connection of a member of said plurality of memory arrays;
wherein all said memory arrays are connected to a least one drain of said set of PFETs.

13) The method as in claim 12 wherein said pluralities of memory arrays are SRAM arrays.

14) The method as in claim 12 wherein said pluralities of memory arrays are register arrays.
